(19) United States
(12) Patent Application Publication
(10) Pub. No.: US 2026/0026347 A1
(43) Pub. Date: Jan. 22, 2026

(54) ELECTRONIC COMPONENT AND EQUIPMENT

(71) Applicant: CANON KABUSHIKI KAISHA, Tokyo (JP)

(72) Inventor: YU KATASE, Kanagawa (JP)

(21) Appl. No.: 19/259,107

(22) Filed: Jul. 3, 2025

(30) Foreign Application Priority Data
Jul. 16, 2024 (JP) 2024-113632

(51) Int. Cl. H01L 23/38; H01L 23/00; H01L 23/10; H10F 39/00

(52) U.S. Cl. CPC H01L 23/38; H01L 23/10; H01L 24/45; H01L 24/48; H10F 39/804; H01L 2224/45124; H01L 2224/48227; H01L 2224/48464

(57) ABSTRACT

An electronic component is provided. The component includes: a base member, a Peltier element; a semiconductor element placed on a placement surface of the base member via the Peltier element; and a frame member arranged so as to surround a side surface of the semiconductor element. A first electrode provided in the semiconductor element is connected, via a conductive wire, to a second electrode provided in the frame member, and the base member and the frame member are bonded by a bonding member having a lower thermal conductivity than the base member.

### BACKGROUND

### Field of the Technology

The present disclosure relates to an electronic component and equipment.

### Description of the Related Art

Japanese Patent Laid-Open No. 2006-191465 describes electronic equipment that comprises a signal processing device and an imaging element arranged on the signal processing device. Japanese Patent Laid-Open No. 2006-191465 also describes that, in order to suppress the temperature rise of each of the signal processing device and the imaging element, a Peltier element is arranged as a cooling member between the signal processing device and the base member of a package.

### SUMMARY

In the arrangement described in Japanese Patent Laid-Open No. 2006-191465, heat on the heat generating side of the Peltier element may be transmitted to the base member, and the heat may further be transmitted from the base member to the signal processing device and the imaging element, which are semiconductor elements, via wirings for supplying signals and power.

Some embodiments of the present disclosure provide a technique advantageous in suppressing the temperature rise of a semiconductor element.

According to some embodiments, an electronic component comprising: a base member; a Peltier element; a semiconductor element placed on a placement surface of the base member via the Peltier element; and a frame member arranged so as to surround a side surface of the semiconductor element, wherein a first electrode provided in the semiconductor element is connected, via a conductive wire, to a second electrode provided in the frame member, and the base member and the frame member are bonded by a bonding member having a lower thermal conductivity than the base member, is provided.

According to some other embodiments, an electronic component comprising: a cooling member; a semiconductor element placed on a placement surface of the cooling member; and a frame member arranged so as to surround a side surface of the semiconductor element, wherein a first electrode provided in the semiconductor element is connected, via a conductive wire, to a second electrode provided in the frame member, and the cooling member and the frame member are bonded by a bonding member having a lower thermal conductivity than the cooling member, is provided.

Features of the present disclosure will become apparent from the following description of embodiments with reference to the attached drawings. The following description of embodiments is described by way of example.

### BRIEF DESCRIPTION OF THE DRAWINGS

FIG. 1 is a sectional view showing an example of the arrangement of an electronic component according to an embodiment;

FIG. 2 is a top view showing an example of the arrangement of the electronic component shown in FIG. 1;

FIGS. 3A and 3B are bottom views each showing an example of the arrangement of the electronic component shown in FIG. 1;

FIG. 4 is a sectional view showing an example of the arrangement of the electronic component shown in FIG. 1;

FIGS. 5A to 5C are sectional views each showing an example of the arrangement of the electronic component shown in FIG. 1;

FIGS. 6A and 6B are views for explaining comparative examples of a method of bonding a conductive wire of the electronic component shown in FIG. 1;

FIG. 7 is a view for explaining a method of bonding the conductive wire of the electronic component shown in FIG. 1;

FIGS. 8A to 8D are sectional views each showing an example of the arrangement of the electronic component shown in FIG. 1;

FIG. 9 is a sectional view showing an example of the arrangement of the electronic component shown in FIG. 1;

FIG. 10 is a sectional view showing an example of the arrangement of a cooling member of the electronic component shown in FIG. 1;

FIGS. 11A to 11C are sectional views each showing a modification of the electronic component shown in FIG. 1;

FIGS. 12A to 12F are sectional views each showing a modification of the electronic component shown in FIG. 1;

FIGS. 13A to 13C are views each showing an example of the arrangement of the cooling member of the electronic component shown in FIG. 1;

FIG. 14 is a sectional view showing a modification of the electronic component shown in FIG. 1;

FIG. 15 is a sectional view showing a modification of the electronic component shown in FIG. 1;

FIGS. 16A and 16B are a sectional view and a bottom view, respectively, showing a modification of the electronic component shown in FIG. 1;

FIGS. 17A and 17B are sectional views each showing an example of the connection of the electronic component shown in FIG. 1 to a mounting board;

FIG. 18A to 18E are sectional views each showing an example of the connection of the electronic component shown in FIG. 1 to the mounting board;

FIGS. 19A to 19C are sectional views each showing a modification of the electronic component shown in FIG. 1; and

FIG. 20 is a view showing an example of the arrangement of equipment incorporating the electronic component according to the embodiment.

### DESCRIPTION OF THE EMBODIMENTS

Hereinafter, embodiments will be described in detail with reference to the attached drawings. Note, the following embodiments are not intended to limit the scope of the claims. Multiple features are described in the embodiments, but it is not the case that all such features are required, and multiple such features may be combined as appropriate. Furthermore, in the attached drawings, the same reference numerals are given to the same or similar configurations, and redundant description thereof is omitted.

Embodiments of the present disclosure will be described in detail below based on the accompanying drawings. In the following description, terms (for example, “upper”, “lower”, “right”, “left” and other terms including these terms) representing specific directions or positions are used, as necessary. These terms are used for easy understanding of the embodiments with reference to the accompanying drawings, and the meanings of the terms do not limit the technical scope of the present disclosure. In this specification, a planar view corresponds to viewing from a direction perpendicular to the light incident surface of a semiconductor layer. A sectional view corresponds to a plane in the direction perpendicular to the light incident surface of the semiconductor layer. If the light incident surface of the semiconductor layer is rough microscopically, the planar view is defined with reference to the light incident surface of the semiconductor layer when viewed macroscopically.

A semiconductor layer includes the first surface where light enters, and a second surface opposite to the first surface. In this specification, a depth direction is a direction from the first surface of the semiconductor layer, where a photodiode (PD) is arranged, toward the second surface. Hereinafter, the “first surface” will sometimes be referred to as the “front surface”, and the “second surface” will sometimes be referred to as the “back surface”. The “depth” of a given point or a give region in the semiconductor layer means the distance from the first surface (front surface) to the point or the region. When there are a point (or region) Z1 having a distance (depth) d1 from the first surface, and a point (or region) Z2 having a distance (depth) d2 from the first surface, and d1>d2 holds, it may be expressed that “Z1 is deeper than Z2” or “Z2 is shallower than Z1”. Furthermore, when there is a point (or region) Z3 having a distance (depth) d3 from the first surface, and d1>d3>d2 holds, it may be expressed that “Z3 is at a depth between Z1 and Z2” or “Z3 is between Z1 and Z2 in terms of the depth direction”.

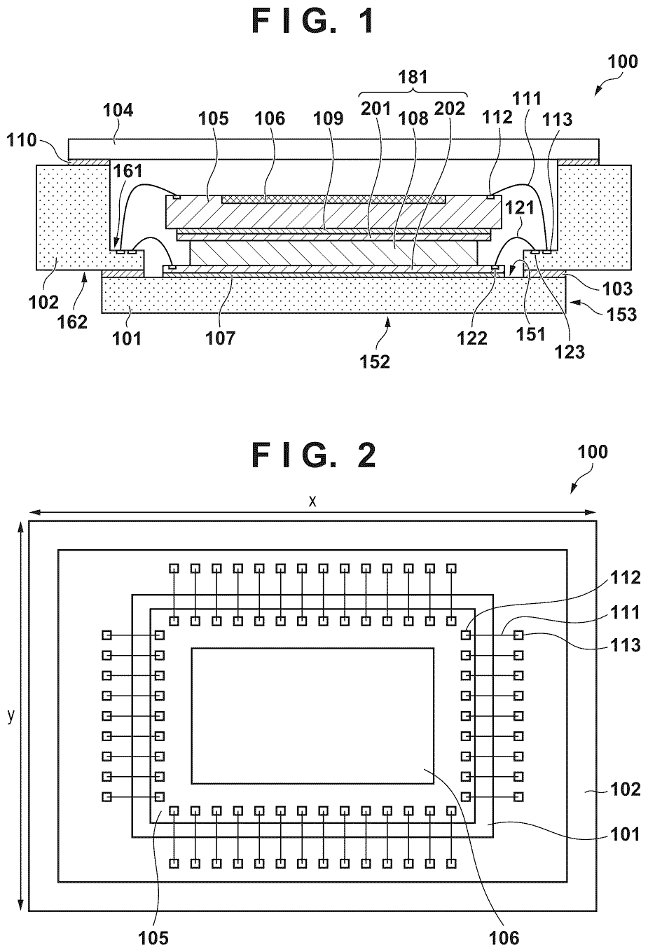

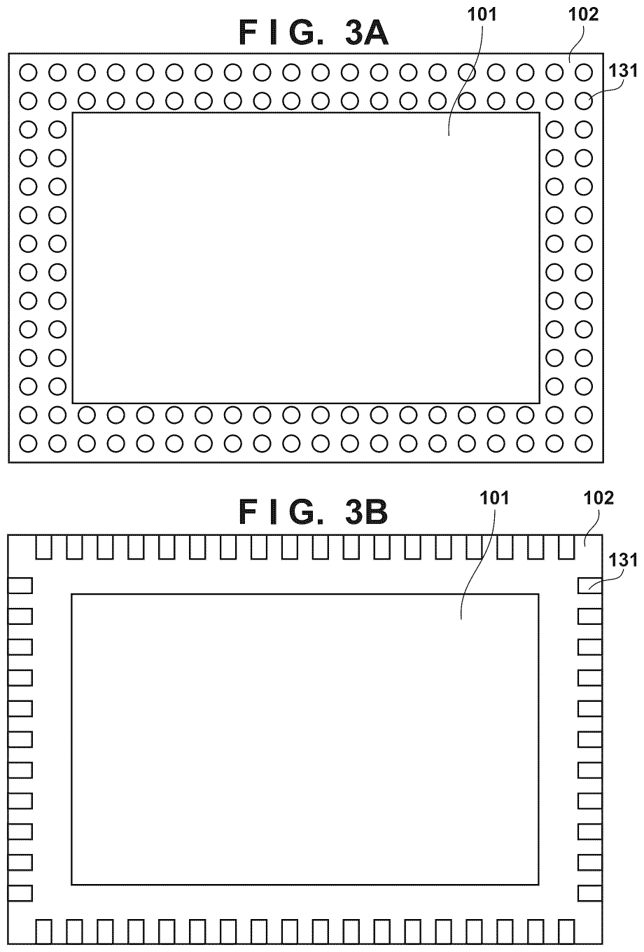

With reference to FIGS. 1 to 19, an electronic component according to an embodiment of the present disclosure will be described. FIG. 1 is a sectional view schematically showing an example of the arrangement of an electronic component 100 in this embodiment. FIG. 2 is a top view of the electronic component 100 in a planar view, and each of FIGS. 3A and 3B is a bottom view of the electronic component 100.

In the electronic component 100 mounted with a semiconductor element 105 including a pixel region 106 where a plurality of pixels including photodiodes are arranged, noise may be generated in signals output from the plurality of pixels due to a temperature change. To reduce the noise, it is conceivable to place a cooling member for cooling the semiconductor element 105 in a package where the semiconductor element 105 is placed. An example of the member used to cool the semiconductor element 105 is a Peltier element. Here, the electronic component 100 including a Peltier element will be described first.

The electronic component 100 includes a base member 101, a Peltier element 108, the semiconductor element 105 placed on a placement surface 151 of the base member 101 via the Peltier element 108, and a frame member 102 arranged so as to surround the side surface of the semiconductor element 105. The electronic component 100 further includes an optical member 104 arranged so as to cover the semiconductor element 105 and bonded to the frame member 102. The base member 101, the frame member 102 bonded to the base member 101 by a bonding member 103, and the optical member 104 bonded to the frame member 102 by a bonding member 110 can also be called the package of the electronic component 100.

The Peltier element 108 is arranged between a base member 201 and a base member 202. The Peltier element 108 can be supplied with power from the outside of the electronic component 100 via an electrode 123 provided in the frame member 102, a conductive wire 121, and an electrode 122 provided in the base member 202. In this specification, the component including the Peltier element 108, the base member 201, and the base member 202 is sometimes referred to as a cooling member 181. The cooling member 181 is bonded to the base member 101 by a bonding member 107. The semiconductor element 105 is bonded to the cooling member 181 by a bonding member 109. During an operation of the electronic component 100 (Peltier element 108), the base member 201 is connected to the heat absorbing side of the Peltier element 108, and the base member 202 is connected to the heat generating side of the Peltier element 108.

An electrode 112 provided in the semiconductor element 105 is connected to an electrode 113 provided in the frame member 102 via a conductive wire 111. A signal or power can be supplied to the semiconductor element 105 from the outside of the electronic component 100 via the conductive wire 111. The conductive wire 111 can also be used to output a signal obtained by the semiconductor element 105 to the outside of the electronic component 100.

The base member 101 can be formed of, for example, a ceramic such as alumina or aluminum nitride as a main material. In other words, the base member 101 can contain at least one of alumina and aluminum nitride. This is because a ceramic such as alumina or aluminum nitride has a high thermal conductivity, so that the heat generated by the Peltier element 108 is easily dissipated to the outside of the package.

Similar to the base member 101, the frame member 102 can be formed of, for example, a ceramic such as alumina or aluminum nitride as a main material. In other words, the frame member 102 can contain at least one of alumina and aluminum nitride. Since the frame member 102 is bonded to the base member 101 via the bonding member 103, by making the arrangement in which a difference in linear expansion coefficient between the base member 101 and the frame member 102 hardly occurs, the bonding reliability improves. Hence, for example, the base member 101 and the frame member 102 may be formed of the same material.

The bonding member 103 that bonds the base member 101 and the frame member 102 may be, for example, a so-called epoxy-based, silicone-based, or acrylic-based adhesive, or may be an epoxy-based, silicone-based, or acrylic-based resin molded product. In other words, the bonding member 103 that bonds the base member 101 and the frame member 102 can contain at least one of an epoxy-based resin, a silicone-based resin, and an acrylic-based resin. In order to suppress that the heat from the heat generating side of the Peltier element 108 is transmitted from the base member 101 to the frame member 102, and further transmitted from the frame member 102 to the semiconductor element 105 via the conductive wire 111, the bonding member 103 needs to have a lower thermal conductivity than the base member 101 and the frame member 102. Therefore, the base member 101 and the frame member 102 are bonded by the bonding member 103 that uses the material as described above having a lower thermal conductivity than the base member 101. In order to suppress heat transmission, for example, it is also conceivable to increase the thickness of the bonding member 103. The thickness and the like of the bonding member 103 will be described later in detail.

The optical member 104 is formed using, for example, glass, quartz, sapphire, or the like. Quartz and sapphire can also function as a low-pass filter (LPF). Sapphire has a higher strength than quartz, and thus can be thinned more than quartz. Therefore, sapphire is advantageous in reducing the overall size of the electronic component 100 (package). In addition, the linear expansion coefficient of sapphire is approximately equal to that of alumina. Accordingly, if the frame member 102 is made of alumina and the optical member 104 is made of sapphire, the bonding reliability can improve.

As for the semiconductor element 105, for example, various elements, circuits, and the like are formed in a semiconductor substrate such as a silicon substrate. In this embodiment, as described above, the semiconductor element 105 is provided with the pixel region 106 where the plurality of pixels each including a photodiode and the like are arranged in an array. The photodiode is an example of a photoelectric conversion element. The semiconductor element 105 may be, for example, a CMOS image sensor. The photodiode included in the pixel may be, for example, an avalanche diode. If the photodiode is an avalanche diode, the semiconductor element 105 may function as a Single Photon Avalanche Diode (SPAD) sensor.

The bonding member 110 that bonds the frame member 102 and the optical member 104 may be, for example, an epoxy-based adhesive. The bonding member 110 may be a UV-curable member, or may be a thermosetting member. A space, which is surrounded by the base member 101, the frame member 102, and the optical member 104 and in which the semiconductor element 105 is arranged, may be maintained in a nitrogen atmosphere or a reduced pressure atmosphere for terminal insulation. Therefore, a member capable of maintaining airtightness and having low moisture permeability can be used for the bonding member 110. To keep the low moisture permeability, the bonding member 110 suitably has a small thickness and a large width. For example, the thickness of the bonding member 110 may be 20 μm or less, or 30 μm or less. The width of the bonding member 110 can be appropriately set from the viewpoint of downsizing of the electronic component 100 (package), bonding reliability, airtightness, moisture permeability, and the like.

For the bonding member 107 that bonds the cooling member 181 and the base member 101, and the bonding member 109 that bonds the cooling member 181 and the semiconductor element 105, a material such as silver paste having a high thermal conductivity may be used. If a space is generated in the bonding surface, this hinders thermal conduction. Therefore, each of the bonding members 107 and 109 may be formed as large as possible on the bonding surface, or may be formed even on the entire bonding surface. The thickness of each of the bonding members 107 and 109 may be, for example, about 100 μm or less, or may further be about 20 to 30 μm.

As in the top view shown in FIG. 2, the rectangular pixel region 106 of the semiconductor element 105 may be arranged in the center of the electronic component 100. Multiple electrodes 112 may be provided on each side of the semiconductor element 105, and each electrode 112 may be connected to the electrode 113 in the frame member 102 via the conductive wire 111. Here, if an electronic component has a length x in the longitudinal direction and a length y in the transverse direction, the electronic component 100 having the lengths x and y of about 20 mm is assumed. However, the size of the electronic component 100 is not limited to this, and may be smaller or larger than this example.

Each of FIGS. 3A and 3B is a planar view of the electronic component 100 from the opposite side of the optical member 104. FIG. 3A shows a schematic view in a case where the package (including the base member 101, the frame member 102, and the optical member 104 as described above) forming the electronic component 100 is a so-called Land Grid Array (LGA) package. FIG. 3B shows a schematic view in a case where the package is a so-called Leadless Ceramic Chip Carrier (LCC) package. The arrangement of electrodes 131 for connecting the package and the outside of the package is not limited to LGA and LCC, but may be, for example, Pin Grid Array (PGA) or the like. LGA can be advantageous from the viewpoint of downsizing since it can achieve the smaller height than other arrangements. An arrangement combining LGA and LCC may be used. The electrode 131 of the LGA or LCC package is connected to the electrode 113 or the electrode 123 via an inner layer wiring pattern (not shown) provided in the frame member 102.

When LGA is used for the package, it is possible to manufacture the package using a reflow oven, and an improvement in productivity can be expected as compared to other methods. However, there is a need to suppress that the solder contained in the Peltier element 108 melts during a reflow process upon mounting the electronic component 100 (package) on a mounting board and causes damage to the Peltier element 108. Therefore, in the mounting process used in the manufacture of the electronic component 100, the reflow process needs to be a low-temperature process, for example, at 200° C. or less. Hence, bonding between the electronic component 100 (package) and the mounting board can be implemented using a low-melting point material such as a resin-reinforced solder.

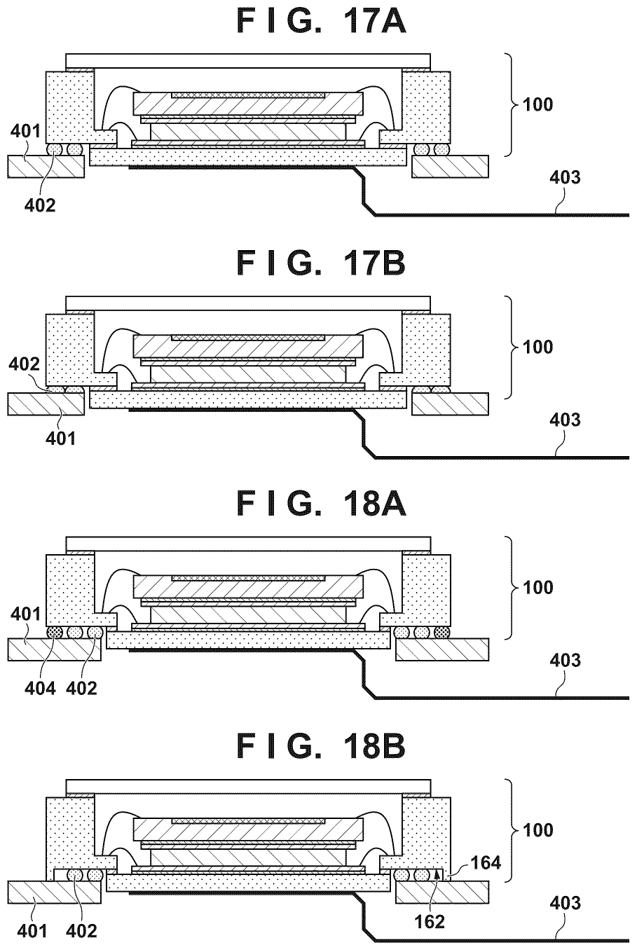

As for the terminal array of the LGA package, as shown in FIG. 3A, a portion where no electrode array exists may be provided in the central portion. To increase the cooling efficiency of the Peltier element 108, it can be important to bond a member having a high thermal conductivity to this portion where the electrode array does not exist, thereby releasing the heat of the base member 101 to the outside. As the member having a high thermal conductivity, for example, a carbon graphite sheet, an alloy plate for a heat spreader, a heat pipe, or the like can be connected to the base member 101. For example, as shown in FIG. 17A, a carbon graphite sheet 403 is bonded to the base member 101. The carbon graphite sheet 403 is made to extend to the outside of the electronic component 100 through an opening portion or the like provided in the mounting board 401. Furthermore, the end portion of the carbon graphite sheet 403 on the right side in FIG. 17A is connected to the housing of a camera module or the like in which the electronic component 100 is mounted. With this, a path for releasing the heat generated by the electronic component 100 to the outside of the electronic component 100 is formed.

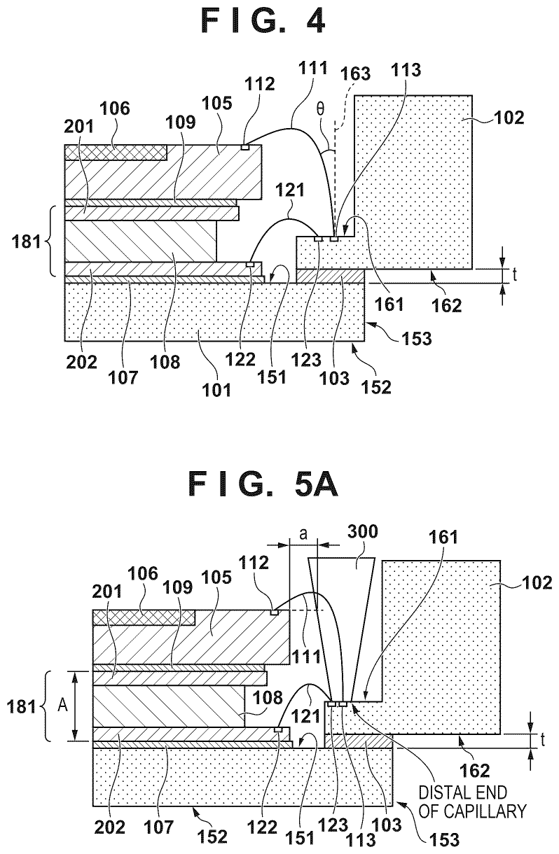

FIG. 4 is a schematic enlarged view of a portion of the electronic component 100 according to this embodiment, where the base member 101 and the frame member 102 are bonded. The frame member 102 can include a surface 161 where the electrode 113 is arranged, and a surface 162 opposite to the surface 161. The frame member 102 can further include an upper surface to which the optical member 104 is bonded, an outside surface which forms the outer edge of the package, an inside surface which faces the space of the package where the semiconductor element 105 is arranged, and the like. In this embodiment, the placement surface 151 of the base member 101, on which the Peltier element 108 is placed, and the surface 162, which is the bottom surface of the frame member 102, are bonded by the bonding member 103. Here, when the bonding member 103 has a thickness t, the thickness t may be, for example, 20 to 30 μm, or may be 100 μm or more. The thickness of the bonding member 103 can be appropriately set from the viewpoint of downsizing of the electronic component 100, airtightness, moisture permeability, and the like, like the bonding member 110 described above, in addition to the viewpoint of thermal conduction.

The electrode 112 provided in the semiconductor element 105 and the electrode 113 provided in the frame member 102 are connected by the conductive wire 111. Here, the angle formed by the conductive wire 111 and a normal 163 to the surface 161 of the frame member 102 where the electrode 113 is arranged is defined as an angle θ. By arranging the electrode 113 at a position close to the semiconductor element 105, downsizing of the electronic component 100 can be implemented. Hence, for example, the conductive wire 111 may rise from the electrode 113 at an angle of 10° or less with respect to the normal 163 to the surface 161 of the frame member 102 where the electrode 113 is arranged. That is, θ≤10° may hold. Here, the rising portion of the conductive wire 111 from the electrode 113 is a portion where the conductive wire 111 starts to extend linearly from a ball or a stitch formed in the bonding portion between the conductive wire 111 and the electrode 113. Therefore, this portion is a portion where the conductive wire 111 is observed relatively macroscopically.

In the electronic component 100 in which the Peltier element 108 is placed together with the semiconductor element 105 as in this embodiment, the conductive wire 111 connecting the semiconductor element 105 and the frame member 102 may have a certain length to suppress heat input from the heat generating side of the Peltier element 108. In the arrangement shown in FIG. 4, the electrode 113 is arranged at a height between the placement surface 151 of the base member 101 and the semiconductor element 105. In order to ensure the wire length of the conductive wire 111, the electrode 113 may be arranged at a lower position, in other words, at a position close to the placement surface 151 of the base member 101. For example, the electrode 113 may be arranged at the same height as the Peltier element 108 of the cooling member 181 between the placement surface 151 of the base member 101 and the semiconductor element 105.

For example, the conductive wire 111 may be arranged so as to reach a position 1 mm or more away from the electrode 113 in the direction of the normal 163 to the surface 161 of the frame member 102 where the electrode 113 is arranged. The height of the conductive wire 111 in the direction of the normal 163 to the surface 161 is decided by the thickness of the Peltier element 108 (cooling member 181), the thickness of the semiconductor element 105, the thickness of the bonding member 103, and the thickness of the frame member 102 between the surface 162 and the surface 161 where the electrode 113 is provided. For example, in order to maintain the thickness of the semiconductor element 105, back grinding may not be performed in the manufacturing process of the semiconductor element 105, and the semiconductor element 105 may have a thickness of about 0.7 to 0.8 mm. If back grinding is not performed in the manufacturing process of the semiconductor element 105, the semiconductor element 105 has a large thickness so that the thermal conductivity in the direction parallel to the main surface of the semiconductor element 105, where the pixel region 106 is provided, increases. This can increase the effect of maintaining a uniform temperature distribution in the surface of the semiconductor element 105. Even if back grinding is performed in the manufacturing process of the semiconductor element 105, by forming the semiconductor element 105 so as to have a thickness of about 0.5 mm, the length of the semiconductor element 105 in the thickness direction (in other words, the length of the conductive wire in the direction of the normal 163) can be ensured.

Similarly, it is possible to increase the length of the conductive wire 111 in the direction of the normal 163 to the surface 161 by increasing the thickness of the Peltier element 108 (cooling member 181). However, if the Peltier element 108 (cooling member 181) is thick, there is a possibility that the capillary used in wire bonding for connecting the conductive wire 111 to the electrodes 112 and 113 interfere with the semiconductor element 105. This will be described later.

The conductive wire 111 may be thinner than conductive wires generally used in semiconductor elements such as an imaging element that is not mounted with the Peltier element 108, and may have a diameter of @15 μm or the like. This is because, by increasing the thermal resistance of the conductive wire 111, a heat flow transmitted from the heat generating side of the Peltier element 108 to the semiconductor element 105 via the base member 101 and the frame member 102 can be suppressed. Furthermore, in order to increase the thermal resistance in the conductive wire 111, a wire used as the conductive wire 111 may be a wire made of a gold alloy, aluminum, or the like as a main material rather than a gold wire. For example, as the conductive wire 111, a wire made of a gold alloy, aluminum, or the like having a thermal conductivity of 300 W/mK or less may be used. The wire diameter of the conductive wire 111 can be decided in accordance with the balance of the allowable current amount, resistance, inductance, and the like to prevent wire breaking. On the other hand, power consumption of the Peltier element 108 is large. Therefore, the conductive wire 121 that electrically connects the electrode 122 provided in the base member 202 and the electrode 123 provided in the frame member 102 to supply power to the Peltier element 108 may have a large wire diameter. For example, the wire diameter of the conductive wire 121 may be larger than the wire diameter of the conductive wire 111.

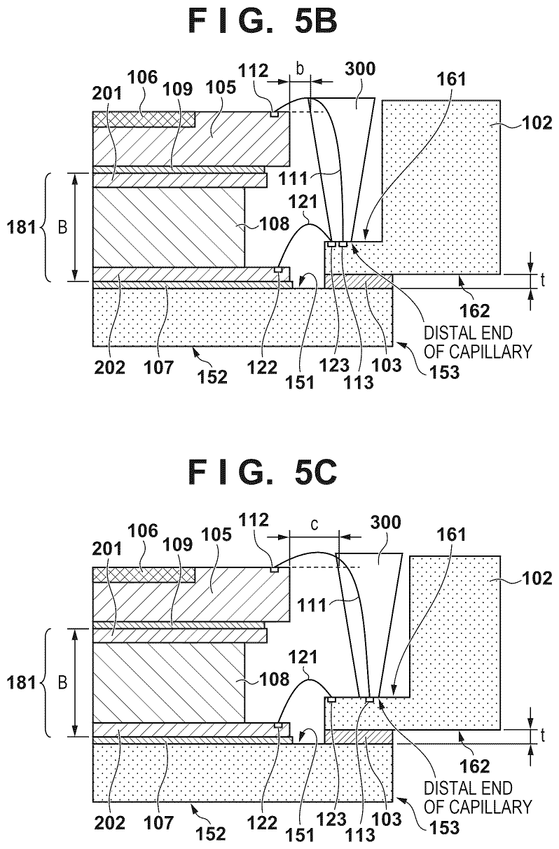

FIGS. 5A to 5C are views for explaining the minimum clearance between a capillary 300 for bonding and the semiconductor element 105. For example, as shown in FIG. 5A, in a case where the cooling member 181 having a thickness A is used, the distance between the upper end of the semiconductor element 105 and a portion of the capillary 300 at the same height as the upper end of the semiconductor element 105 and closest to the semiconductor element 105 is defined as a distance a. On the other hand, as shown in FIG. 5B, in a case where the cooling member 181 having a thickness B is used, the distance between the upper end of the semiconductor element 105 and a portion of the capillary 300 at the same height as the upper end of the semiconductor element 105 and closest to the semiconductor element 105 is defined as a distance b. For example, when the same frame member 102 and the bonding member 103 are used, if the thickness relationship is expressed as A<B, the distance relationship is expressed as a>b.

The minimum clearance between the semiconductor element 105 and the capillary 300 changes in accordance with the size of the semiconductor element 105 and the position of the electrode 113. Even if the cooling member 181 having the thickness B is used as in FIG. 5B, by shifting the position of the electrode 113 in the direction away from the semiconductor element 105 as shown in FIG. 5C, a distance c between the semiconductor element 105 and the capillary 300 can be ensured. It is also possible to ensure the distance c by bringing the surface 161 of the frame member 102, where the electrode 113 is arranged, close to the semiconductor element 105, that is, by shifting the surface 161 upward.

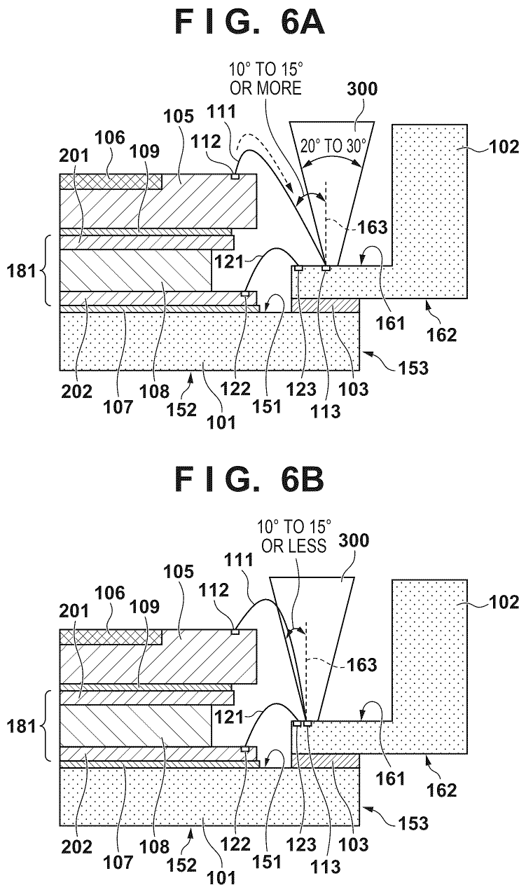

FIGS. 6A and 6B are views for explaining the relationship between the angle of the conductive wire 111 and the capillary 300 when performing general wire bonding. FIG. 6A is a view showing a case where the angle θ formed by the conductive wire 111 and the normal 163 to the surface 161 of the frame member 102 where the electrode 113 is arranged is larger than 10° to 15°. FIG. 6B is a view showing a case where the angle θ is smaller than 10° to 15°.

In wire bonding as shown in FIG. 6A, a wire loop is formed after the electrode 112 and the conductive wire 111 are bonded, and the electrode 113 and the conductive wire 111 are bonded by stitch bonding. In this case, the distal end portion of the capillary 300 used for bonding has an angle of about 20° to 30° in a section. Consider a case where, as shown in FIG. 6B, bonding is performed in a state in which the angle θ between the conductive wire 111 and the normal 163 is steeper than the angle of the distal end portion of the capillary 300. In this case, since the capillary 300 and the conductive wire 111 interfere with each other, bonding may not be possible. To increase the angle θ, there needs to be some space in the horizontal direction between the electrode 113 and the end portion of the frame member 102. This can hinder downsizing of the electronic component 100.

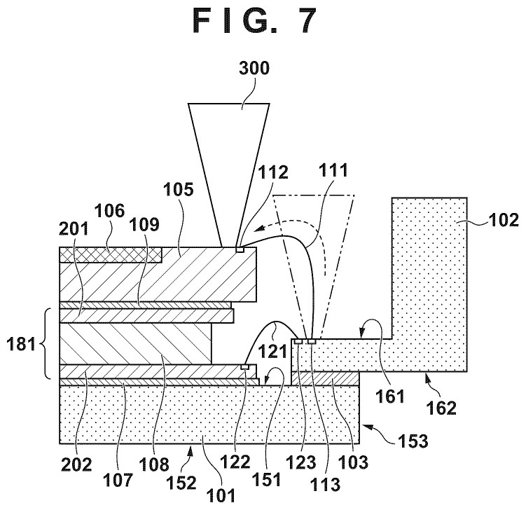

FIG. 7 is a view for explaining the relationship between the angle of the conductive wire 111 and the capillary 300 when performing wire bonding using a ball stitch on bonding (BSOB) method. In the BSOB method, a ball is first formed on the electrode 113. Then, the electrode 113 and the conductive wire 111 are bonded, the capillary 300 is lifted substantially vertically, and the electrode 112 and the conductive wire 111 are bonded. That is, a ball is formed between the conductive wire 111 and the electrode 112 in the bonding portion between the conductive wire 111 and the electrode 112, and a ball is formed between the conducive wire 111 and the electrode 113 in the bonding portion between the conducive wire 111 and the electrode 113. Furthermore, a stitch is formed and bonded on the ball in the bonding portion between the electrode 112 and the conductive wire 111. In the BSOB method, as long as the distance for bonding the conductive wire 111 and the electrode 113 is ensured, no interference between the capillary 300 and the conductive wire 111 occurs when bonding the conductive wire 111 to the semiconductor element 105 regardless of the distance between the electrode 113 and the end portion of the frame member 102. Therefore, as compared to the case where the conductive wire 111 is bonded as shown in each of FIGS. 6A and 6B, the BSOB method can reduce the space in the horizontal direction. As a result, downsizing of the electronic component 100 is implemented.

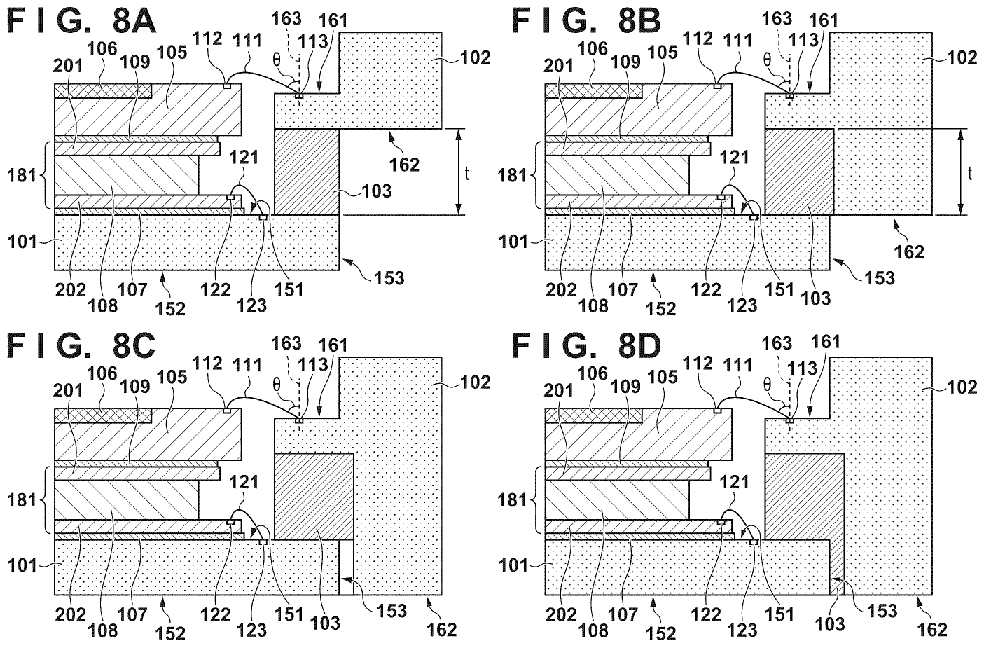

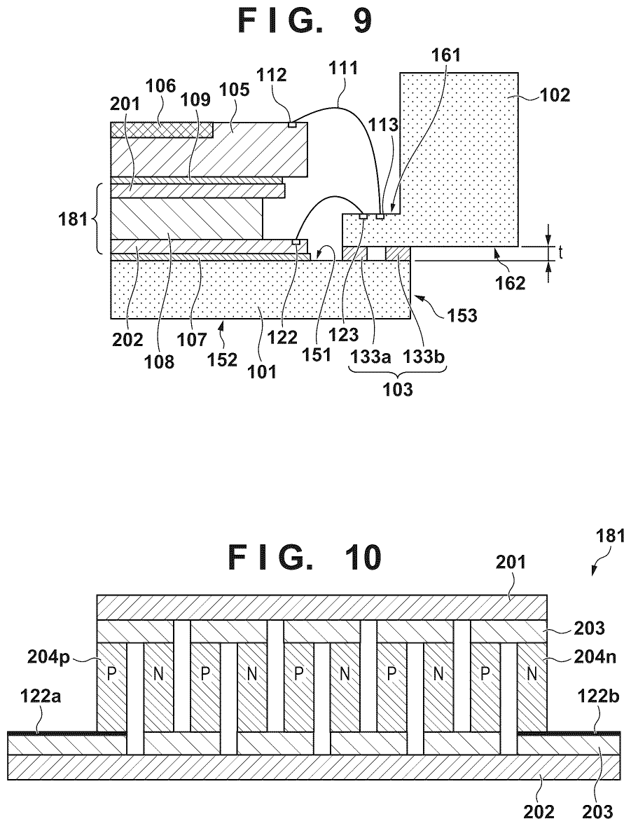

Each of FIGS. 8A to 8D and FIG. 9 is a schematic enlarged view of the bonding portion between the base member 101 and the frame member 102 of the electronic component 100 according to this embodiment, and shows a modification of the arrangement shown in FIG. 4. The main differences from the arrangement shown in FIG. 4 are the thickness t of the bonding member 103 and the rising angle θ of the conductive wire 111 with respect to the normal 163 to the surface 161 of the frame member 102 where the electrode 113 is arranged.

For example, as shown in FIG. 8A, when the thickness t of the bonding member 103 is as large as the thickness of the Peltier element 108, the surface 161 of the frame member 102 where the electrode 113 is provided approaches the height of the surface of the semiconductor element 105 where the electrode 112 is provided. In this arrangement, even in normal wire bonding in which the conductive wire 111 is bonded to the electrode 112 and then the conductive wire 111 is bonded to the electrode 113, since the amount of downward movement decreases, it is possible to decrease the distance between the electrode 112 and the electrode 113 while suppressing the interference between the capillary 300 and the upper end of the semiconductor element 105. As a result, it is possible to reduce the space in the horizontal direction. In this case, the angle θ is larger than 10°, and the length of the conductive wire 111 is shorter than that in a case where the thickness t is small. When the length of the conductive wire 111 decreases, the thermal resistance decreases. However, by the bonding member 103 having an enough thickness, the effect of suppressing a heat flow from the heat generating side of the Peltier element 108 can be obtained. In addition, since there is no need to use the BSOB method, the number of steps in the wire bonding process can be reduced. The amount of downward movement of the wire bonding can also be decreased by increasing the thickness of the frame member 102 so that the surface 161 of the frame member 102 where the electrode 113 is provided becomes high, rather than increasing the thickness t of the bonding member 103. However, when the thickness t of the bonding member 103 having a low thermal conductivity is small and the thickness of the frame member 102 having a high thermal conductivity is large, the heat from the heat generating side of the Peltier element 108 may not be sufficiently suppressed.

As shown in FIG. 8B, the frame member 102 and the bonding member 103 may be formed so that two surfaces of the bonding member 103 contact two surfaces of the frame member 102, respectively. In the arrangement shown in FIG. 8B, the frame member 102 is in contact with two surfaces of the bonding member 103 on the outer edge side. When the thickness t of the bonding member 103 is large, the step between the surface 162 as the back surface of the frame member 102 and the back surface of the base member 101 can make it difficult to perform bonding with the mounting board 401, which will be described later. Accordingly, the structure that does not increase the step between the surface 162 of the frame member 102 and the back surface of the base member 101 more than necessary, as shown in FIG. 8B, may be employed. Furthermore, as shown in FIG. 8C, the surface 162 of the frame member 102 may be arranged at the same height as a surface 152 as the bottom surface of the base member 101. In this case, the bonding member 103 may not be in contact with a side surface 153 of the base member 101 as shown in FIG. 8C, or may be in contact with the side surface 153 of the base member 101 as shown in FIG. 8D. As shown in FIGS. 8A to 8D, the electrode 123 for supplying power to the Peltier element 108 may be provided not in the frame member 102 but the placement surface 151 of the base member 101. In this case, an electrode for connection with the mounting board, which is electrically connected to the electrode 123, can be arranged in the surface 152 opposite to the placement surface 151 of the base member 101.

As shown in FIG. 9, the bonding member 103 may be formed from a plurality of members including a member 133a and a member 133b. In this case, the bonding portion between the base member 101 and the frame member 102 includes a space surrounded by the base member 101, the frame member 102, the member 133a, and the member 133b. That is, a hollow layer where the bonding member 103 is not formed may be arranged between the base member 101 and the frame member 102. For example, the thermal conductivity of a general epoxy-based resin is about 0.1 to 0.8 W/m·K. On the other hand, the thermal conductivity of air is about 0.0241 W/m·K. Therefore, it is possible to suppress a heat flow from the heat generating side of the Peltier element 108 more than in a case of the integral bonding member 103. Note that, when the bonding member 103 is extremely small, the bonding reliability between the base member 101 and the frame member 102 can decrease. Accordingly, the member 133a and the member 133b are formed to have appropriate sizes in consideration of the bonding reliability.

In any of the above-described arrangements, each arrangement of the electronic component 100 can be designed from the viewpoint of downsizing of the electronic component 100, suppression of a heat flow from the heat generating side of the Peltier element 108, bonding reliability, and other performances. However, by adopting the arrangement as described above, it is possible to suppress a heat flow from the heat generating side of the Peltier element 108 to the semiconductor element 105. Hence, the electronic component 100 in which the temperature rise of the semiconductor element 105 is suppressed can be implemented.

With reference to FIGS. 10 to 14, the Peltier element 108 used in the electronic component 100 according to this embodiment will be described. FIG. 10 is a view for explaining an example of the arrangement of the Peltier element 108 arranged in the cooling member 181. The Peltier element 108 has an arrangement in which p-type semiconductors 204p and n-type semiconductors 204n are alternately connected in a π shape by metal electrodes 203. The Peltier element 108 is arranged between the base member 201 and the base member 202, and supported by the base members 201 and 202.

The base member 201 and the base member 202 function as a heat sink. When functioning as the cooling member 181 arranged in the electronic component 100, the surface of the base member 201 on the semiconductor element 105 side can be a heat absorbing surface, and the surface of the base member 202 on the base member 101 side can be a heat generating surface. For the base members 201 and 202, for example, a ceramic such as alumina or aluminum nitride may be used. Furthermore, processing such as gold plating may be performed on the surfaces of the base members 201 and 202 to increase the thermal conductivity. For example, the base member 101 and the base member 202 may be formed of the same material. By making the arrangement in which a difference in linear expansion coefficient between the base member 101 and the base member 202 hardly occurs, the bonding reliability improves. The above-described electrode 122 is arranged to supply power to the Peltier element 108. For example, an electrode 122a is an electrode connected to a power supply potential VDD, and an electrode 122b is an electrode connected to a ground potential GND.

When a voltage V is applied to the Peltier element 108, a current I flows. Let T_{c} be the temperature on the heat absorbing side, and Tₕ be the temperature on the heat generating side. When the Seebeck coefficient is a, the internal resistance is R, the thermal conductivity is λ, and the temperature difference between the heat absorbing side and the heat absorbing side is ΔT, a heat absorption amount Q_{c} is expressed by:

Q_{c}=αT_{c}I−λΔT−(½)RI² (1)

That is, in order to increase the heat absorption amount Q_{c} of the Peltier element 108, it is conceivable to decrease the thermal conductivity λ and the internal resistance R.

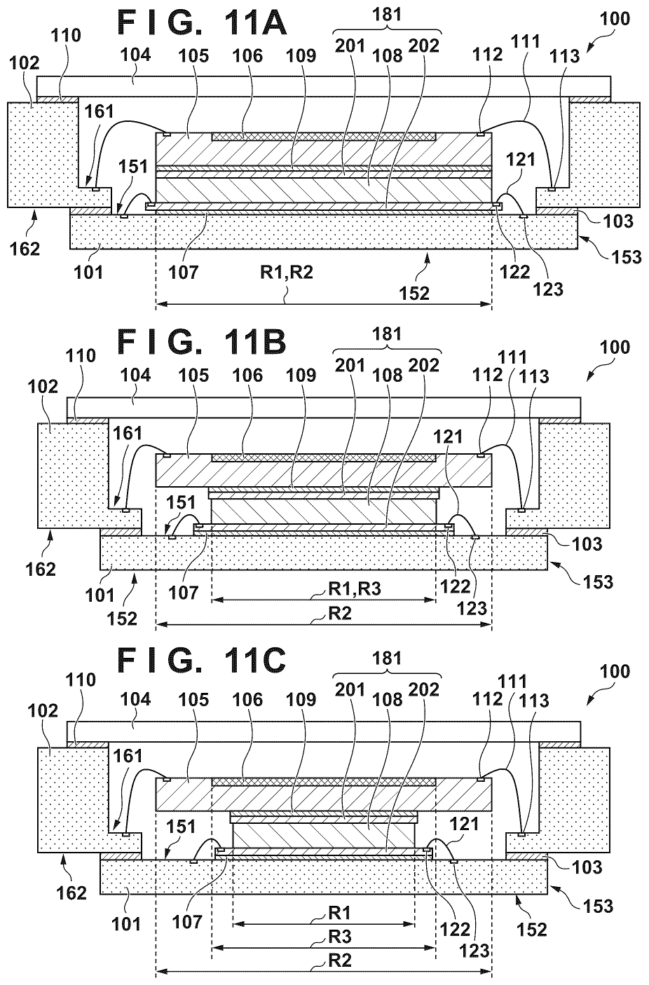

Next, with reference to FIGS. 11A to 11C, variations of the arrangement of the Peltier element 108 will be described. Here, in this specification, the outer edge of the Peltier element 108 is defined in an orthogonal projection to the placement surface 151 of the base member 101 when the cooling member 181 including the Peltier element 108 is placed on the base member 101. The outer edge of the Peltier element 108 is defined by the outermost p-type semiconductor 204p and the outermost n-type semiconductor 204n among the p-type semiconductors 204p and the n-type semiconductors 204n arranged in the Peltier element 108, and virtual lines connecting the outer edges thereof in the orthogonal projection to the placement surface 151. As shown in FIGS. 11A to 11C, in the orthogonal projection to the placement surface 151 of the base member 101, the region surrounded by the outer edge of the Peltier element 108, in other words, the region where the Peltier element 108 is arranged, is shown as a region R1. In addition, in the orthogonal projection to the placement surface 151 of the base member 101, the region where the semiconductor element 105 is arranged is shown as a region R2. Similarly, as shown in FIG. 11C, in the orthogonal projection to the placement surface 151 of the base member 101, the region of the semiconductor element 105 where the pixel region 106 is arranged is shown as a region R3.

In the electronic component 100 shown in FIG. 11A, the size of the Peltier element 108 is the same as that of the semiconductor element 105. In other words, the region R1 and the region R2 have the same size. In this case, it is possible to evenly cool the surface of the semiconductor element 105. However, since the thermal conductivity λ in the above equation (1) becomes high and the power consumption increases, the heat dissipation amount on the heat generating side also increases. Along with this, it becomes difficult to suppress a heat flow passing through the base member 101, the frame member 102, and the conductive wire 111 from the heat generating side of the Peltier element 108, and this can lead to an increase in total power consumption of the electronic component 100. In addition, when the electrode 123 for supplying power to the Peltier element 108 is provided not in the frame member 102 but in the base member 101, there needs to be an electrode space in the base member 101 outside the region R1. This can be disadvantageous in terms of downsizing of the electronic component 100.

In the electronic component 100 shown in FIG. 11B, in the orthogonal projection to the placement surface 151 of the base member 101, the outer edge of the Peltier element 108 is arranged inside the outer edge of the semiconductor element 105. That is, the region R1 where the Peltier element 108 is arranged has a size that is included within the region R2 where the semiconductor element 105 is arranged. Furthermore, the size of the Peltier element 108 is the same as the size of the pixel region 106 of the semiconductor element 105. In other words, the region R1 and the Region R3 have the same size. In this case as well, it is possible to evenly cool the surface of the semiconductor element 105, but the thermal conductivity 2 is high and the power consumption increases. Accordingly, it becomes difficult to suppress a heat flow passing through the base member 101, the frame member 102, and the conductive wire 111 from the heat generating side of the Peltier element 108, and this can lead to an increase in total power consumption of the electronic component 100.

In the electronic component 100 shown in FIG. 11C, in the orthogonal projection to the placement surface 151 of the base member 101, the outer edge of the Peltier element 108 is arranged inside the outer edge of the semiconductor element 105. That is, the region R1 where the Peltier element 108 is arranged has a size that is included within the region R2 where the semiconductor element 105 is arranged. Furthermore, in the orthogonal projection to the placement surface 151 of the base member 101, the outer edge of the Peltier element 108 is arranged inside the outer edge of the pixel region 106. That is, the region R1 where the Peltier element 108 is arranged is smaller than the region R3 where the pixel region 106 is arranged.

In general, in the Peltier element 108, the smaller the area on the heat absorbing side, the lower the thermal conductivity λ can be. However, along with this, the heat absorption amount Q_{c} also decreases. Therefore, it is important to select the Peltier element 108 including the proper number of the p-type semiconductors 204p and n-type semiconductors 204n. For example, as described above, when the temperature on the heat absorbing side of the Peltier element 108 is T_{c}, the temperature on the heat generating side is Tₕ, and the thermal resistance of the whole conductive wire 111 arranged in the electronic component 100 is R_{w}, heat P_{w} transmitted through the conductive wire 111 and entering from the base member 101 to the semiconductor element 105 is expressed by:

P_{w}=(Tₕ−T_{c})/R_{w} (2)

To keep the temperature T_{c} for cooling the semiconductor element 105 constant, the sum of the power consumption Pₛ in the semiconductor element 105 and the heat P_{w} transmitted through the conductive wire 111 needs to be equal to the heat absorption amount Q_{c} of the Peltier element 108. In order to suppress power consumption Pₚ of the Peltier element 108 under the condition as described above, it is necessary to select the Peltier element including the number of p-type semiconductors 204p and the n-type semiconductors 204n that increases COP=Q_{c}/Pₚ, where COP is the ratio of the heat absorption amount Q_{c} to the power consumption Pₚ of the Peltier element 108.

When a widely mass-produced bismuth-telluride-based Peltier element is used as the Peltier element 108 according to this embodiment to cool the semiconductor element 105, the efficiency can be improved with the Peltier element 108 smaller than the semiconductor element 105 as shown in FIG. 11C. That is, by selecting the Peltier element 108 including the relatively small number of the p-type semiconductors 204p and n-type semiconductors 204n, that is, the Peltier element 108 having the low thermal conductivity 2, it is possible to efficiently absorb heat, and in many cases, it is possible to suppress the total power consumption of the electronic component 100.

In the arrangement shown in FIG. 11C, the electrode 112 is arranged at a position overlapping the hollow region where the Peltier element 108 (cooling member 181) is not arranged under the semiconductor element 105. In this case, when bonding the electrode 112 and the conductive wire 111, it may be difficult for the heat and ultrasonic wave from a stage for wire bonding arranged below the package to be transmitted to the bonding portion between the electrode 112 and the conductive wire 111. In addition, the region of the Peltier element 108 (cooling member 181) supporting the semiconductor element 105 is small. Hence, when bonding the electrode 112 and the conductive wire 111, a load may be applied to bonding via the bonding member 109 between the semiconductor element 105 and the cooling member 181 based on the principle of leverage. Furthermore, temperature unevenness can be generated in the surface of the semiconductor element 105.

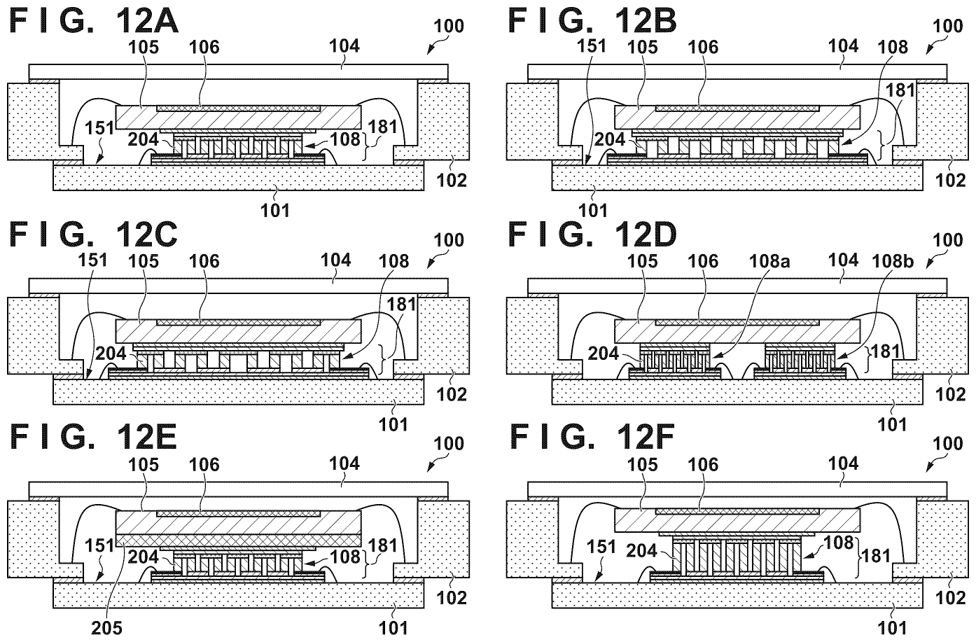

While considering the problems described above, a further example of the arrangement of the Peltier element 108 (cooling member 181) will be described with reference to FIGS. 12A to 12F. In FIGS. 12A to 12F, in order to suppress the complexity of the drawings, reference numerals are given to only some components of the electronic component 100, but the electronic component 100 includes components similar to those described above.

In the electronic component 100 shown in FIG. 12A, similar to the electronic component shown in FIG. 11C, in the orthogonal projection to the placement surface 151, the region R1 where the Peltier element 108 is arranged is smaller than the region R3 where the pixel region 106 of the semiconductor element 105 is arranged. For example, a case is assumed in which the semiconductor element 105 has a size of about 15.5 mm×11.2 mm (the pixel region has a size of 13 mm×10 mm), and the Peltier element 108 has a size of about 6 mm×6 mm. As described above, this arrangement can have a problem in terms of the wire bondability, the bonding strength between the semiconductor element 105 and the cooling member 181, and temperature unevenness.

In the electronic component 100 shown in FIG. 12B, the number of the p-type semiconductors 204p and n-type semiconductors 204n (to be sometimes simply referred to as the semiconductors 204 hereinafter) included in the Peltier element 108 and the thermal resistance are the same as those in the arrangement shown in FIG. 12A. On the other hand, in the electronic component 100 shown in FIG. 12B, the size of the base member 201, which serves as the heat sink of the Peltier element 108, in the x and y directions (shown in FIG. 2) is enlarged. In the orthogonal projection to the placement surface 151, the outer edge of the Peltier element 108 is extended outside the outer edge of the pixel region 106. The outer edge of the Peltier element 108 may be extended, for example, up to the position overlapping the electrode 112. With this arrangement, it is possible to increase the region for supporting the semiconductor element 105 by the Peltier element 108 (cooling member 181) while maintaining the cooling capability of the Peltier element 108 and the ratio COP shown in FIG. 12A. This facilitates wire bonding, and is expected to suppress temperature unevenness and improve the bonding strength between the semiconductor element 105 and the cooling member 181.

In the electronic component 100 shown in FIG. 12C, the arranging interval of the semiconductors 204 is changed from the Peltier element 108 shown in FIG. 12B. More specifically, the semiconductors 204 are arranged sparsely in the region close to the center of the Peltier element 108, and are arranged densely on the outer edge side. Even in this case, the cooling capability, the thermal resistance, and the ratio COP are the same as those of the Peltier elements 108 shown in FIGS. 12A and 12B. On the other hand, by forming the Peltier element 108 as shown in FIG. 12C, wire bonding is facilitated and temperature unevenness can be suppressed. Furthermore, by densely arranging the semiconductors 204 on the outer edge side of the Peltier element 108, the strength during wire bonding is ensured. This can improve reliability (for example, temperature cycle durability or the like) in the electronic component 100 after manufacturing.

In the electronic component 100 shown in FIG. 12D, a plurality of Peltier elements 108a and 108b are arranged. The Peltier elements 108a and 108b can be, for example, Peltier elements smaller than the Peltier element 108 shown in each of FIGS. 12B and 12C. The plurality of Peltier elements 108a and 108b may be connected in series, or may be connected in parallel. When the Peltier elements 108a and 108b are connected in series, the current I increases. When the Peltier elements 108a and 108b are connected in parallel, the voltage V increases. Two Peltier elements 108a and 108b are shown in the sectional view shown in FIG. 12D, but the number of the Peltier elements 108 arranged in the electronic component 100 is not limited thereto, and three or more Peltier elements 108 may be arranged. By adopting the arrangement as shown in FIG. 12D, wire bonding is facilitated and temperature unevenness can be suppressed. Wire bonding is facilitated, temperature unevenness can be suppressed, and the bonding strength between the semiconductor element 105 and the cooling member 181 can be ensured.

FIG. 12E is a view showing the electronic component 100 including the small Peltier element 108 similar to that shown in FIG. 12A. As compared to the arrangement shown in FIG. 12A, the electronic component 100 shown in FIG. 12E includes a heat spreader 205 between the semiconductor element 105 and the cooling member 181. The heat spreader 205 is arranged to promote heat conduction between the semiconductor element 105 and the cooling member 181 and reinforce the strength of the semiconductor element 105 during wire bonding.

As the heat spreader 205, for example, a plate using a copper alloy or the like can be used. The heat spreader 205 may have a thickness of about 0.5 mm, and may be arranged in the whole region below the semiconductor element 105. In this case, in order to prevent the thickness of the electronic component 100 from becoming excessively large, the semiconductor element 105 may be thinned by back grinding upon manufacturing the semiconductor element 105.

Even with the arrangement shown in FIG. 12E, wire bonding is facilitated, and the effect of suppressing temperature unevenness, ensuring the bonding strength between the semiconductor element 105 and the cooling member 181, and the like can be obtained.

In the electronic component 100 shown in FIG. 12F, the Peltier element 108 whose size in a planar view is the same as that of the Peltier element 108 shown in FIG. 12A but whose height is larger than that of the Peltier element 108 shown in FIG. 12A is arranged. If the sectional area in a direction crossing the current flow direction in the semiconductor 204 is the same, the larger the height of the Peltier element 108, the smaller the current I and the higher the voltage V during the operation of the Peltier element 108. The smaller the current I, the more the Joule loss in the wiring pattern connected to the Peltier element 108 is suppressed. Accordingly, the power consumption of the entire electronic component 100 can be suppressed.

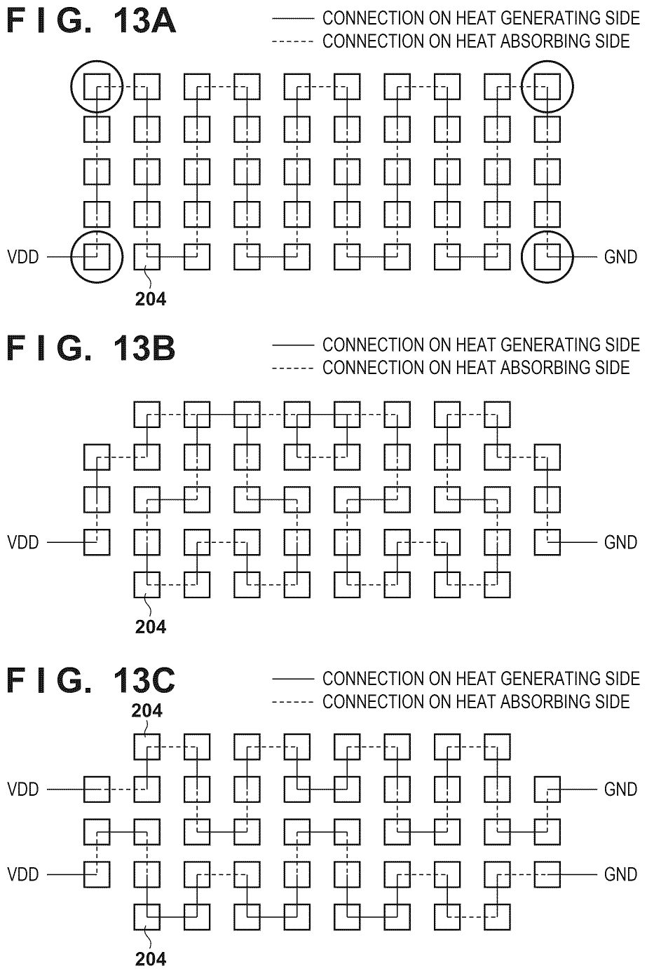

Each of FIGS. 13A to 13C shows an example of the arrangement of the semiconductors 204 in the Peltier element 108 arranged in the electronic component 100 shown in FIG. 12C. FIG. 13A is a top view showing the connection relationship between the semiconductors 204 of the Peltier element 108. The pillar-shaped semiconductors 204 are arranged in an array. The connection on the heat generating side indicated by a solid line connects the semiconductors 204 on the near (or far) side in the drawing, and the connection on the heat absorbing side indicated by a dotted line connects the semiconductors 204 on the far (or near) side in the drawing. The semiconductors 204 are connected from the electrode (the electrode 122a shown in FIG. 10) connected to the power supply potential VDD to the electrode (the electrode 122b shown in FIG. 10) connected to the ground potential GND in a single stroke.

FIG. 13B shows, as an example of the arrangement of the semiconductors 204 in the Peltier element 108, the arrangement in which, when arranging the semiconductors 204 in an array, the semiconductors 204 are not arranged in four corners of the array. The arrangement shown in FIG. 13B can improve the reliability of the Peltier element 108. This is because, when an internal stress is generated in the semiconductor 204 due the temperature difference between the high temperature side (heat generating side) and the low temperature side (heat absorbing side) of the Peltier element 108 that causes thermal expansion on the high temperature side (heat generating side) and thermal contraction on the low temperature side, this stress is highest in the semiconductors 204 in the four corners.

In the arrangement shown in FIG. 13B, one semiconductor 204 is removed from each corner of the array of the semiconductors 204 arranged in the array, but multiple semiconductors 204 such as three or four semiconductors 204 may be removed from each corner. In addition, the connection relationship between the semiconductors 204 is not limited to the form shown in FIG. 13B, and may be any form as long as they are connected from the power supply potential VDD to the ground potential GND in a single stroke. Alternatively, as shown in FIG. 13C, the semiconductors 204 connected from the power supply potential VDD to the ground potential GND in a single stroke may be provided in parallel.

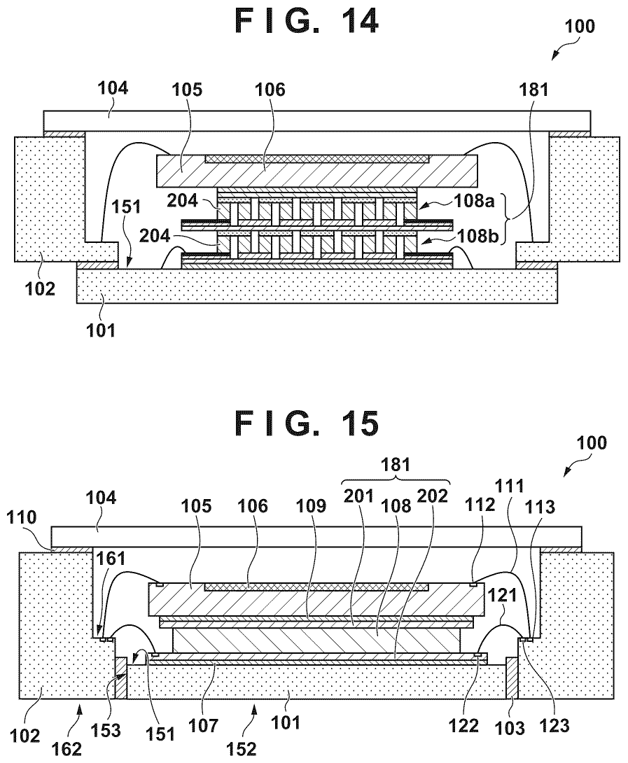

In the electronic component 100 shown in FIG. 14, the plurality of Peltier elements 108a and 108b are arranged, like the arrangement shown in FIG. 12D. On the other hand, unlike the arrangement shown in FIG. 12D, the plurality of Peltier elements 108a and 108b are stacked between the placement surface 151 and the semiconductor element 105. In this case, the base member 202 of the Peltier element 108a on the semiconductor element 105 side may also serve as the base member 201 of the Peltier element 108b on the base member 101 side. By overlapping the plurality of Peltier elements 108, it can be expected that the temperature difference ΔT between the temperature T_{c} on the heat absorbing side and the temperature Tₕ on the heat generating side as the entire cooling member 181 is increased. In FIG. 14, reference numerals are given to only some components, as in FIGS. 12A to 12F, but the electronic component 100 includes components similar to those described above.

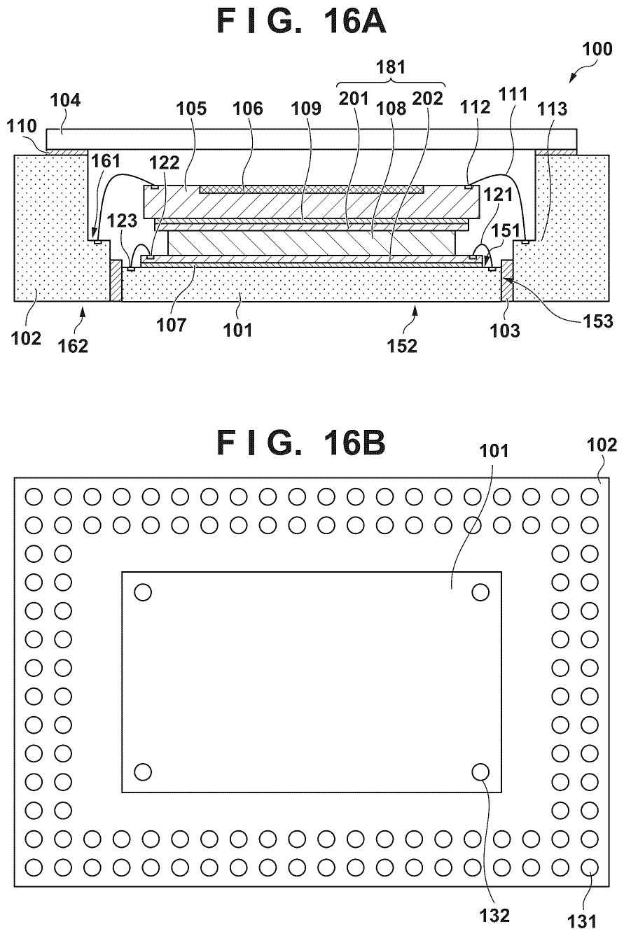

Next, with reference to FIGS. 15 to 16B, modifications of the electronic component 100 described above will be described. In the electronic components 100 described in the above-described embodiment, the bonding member 103 bonds the placement surface 151 of the base member 101 and the frame member 102. However, the present disclosure is not limited to this. Similar to the electronic component 100 (package) shown in FIG. 15, the bonding member 103 may bond the side surface 153 of the base member 101 and the frame member 102. For example, the side surface 153 as the outer edge of the base member 101 and the inside surface of the frame member 102 may be bonded via the bonding member 103. With this, the entire region of the surface 162, which is the back surface of the frame member 102 opposite to the surface 161 where the electrode 123 is arranged, can be used as a region for arranging the electrodes 131 of the LGA package or the LCC package.

Furthermore, as shown in FIG. 16A, the Peltier element 108 may be supplied with power via the electrode 123 provided in the placement surface 151 of the base member 101. A member that connects the Peltier element 108 and the electrode 123 of the base member 101 may be not the conductive wire 121 but a conductive adhesive such as silver paste, or a solder. Alternatively, as shown in FIG. 16B, an electrode 132 electrically connected to the electrode 123 may be provided in the surface 152 of the base member 101 opposite to the placement surface 151. By separating the region for forming the electrodes 131 arranged in the frame member 102 and connected to the semiconductor element 105 and the region for forming the electrodes 132 arranged in the base member 101 and connected to the Peltier element 108, for example, it is possible to reduce the number of the electrodes 131 arranged in the surface 162 of the frame member 102. Accordingly, downsizing of the electronic component 100 in the x and y directions is possible. In addition, since the inner layer wiring pattern in the frame member 102 can be limited to only the wiring pattern corresponding to the semiconductor element 105, the degree of freedom in designing the inner layer wiring pattern can be improved.

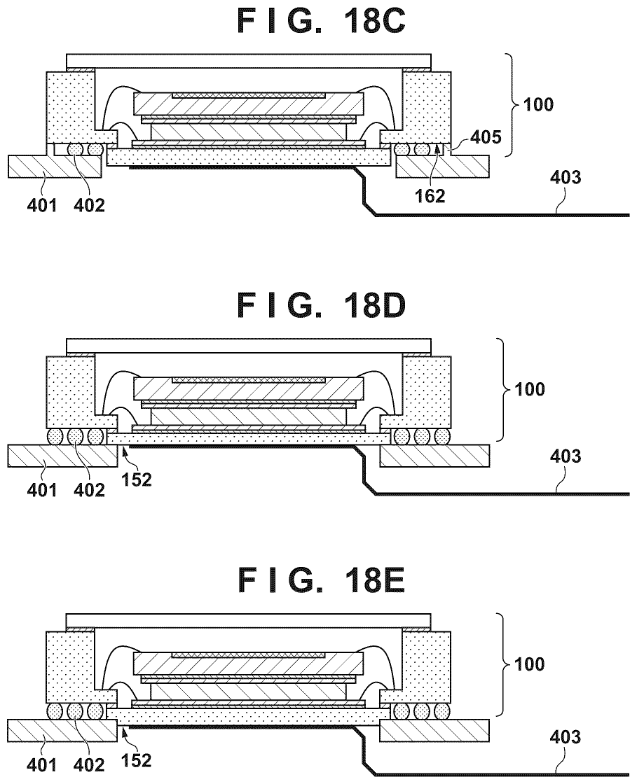

Next, with reference to FIGS. 17A to 18E, mounting of the electronic component 100 on the mounting board 401 will be described. In FIGS. 17A to 18E, in order to suppress the complexity of the drawings, reference numerals are given to only some components of the electronic component 100, but the electronic component 100 includes components similar to those described above.

When the package configuration of the electronic component 100 is, for example, LGA, the electronic component 100 is mounted on the secondary board by reflow mounting. Here, the secondary board is, for example, the mounting board 401 such as a printed circuit board (PCB). As described above, in the orthogonal projection to the placement surface 151 of the base member 101, the surface 162 of the frame member includes a portion arranged outside the base member 101, and the electrodes 131 are provided in this portion. The electrode 131 of the LGA package or the like is connected to an electrode provided in the mounting board 401 via a solder 402. As described above, when mounting the electronic component 100 (package) on the mounting board 401, there is a need to prevent the solder contained in the Peltier element 108 from melting and causing damage to the Peltier element 108. Therefore, for the solder 402, a low-melting point material such as a resin-reinforced solder, that can be used in a reflow oven at a low temperature of 200° C. or less or further 180° C. or less, is used.

The mounting board 401 may include an opening portion as shown in FIG. 17A. In this case, the mounting board 401 may include a thermal path for heat dissipation through the opening portion by a member having a high thermal conductivity, for example, the carbon graphite sheet 403. Due to the opening portion, in the orthogonal projection to the placement surface 151 of the base member 101, the Peltier element 108 may be arranged at a position not overlapping the mounting board 401. However, the opening portion provided in the mounting board 401 is not an essential component.

The weight of the electronic component 100 according to this embodiment can increase due to the Peltier element 108 mounted thereon. Therefore, there is a concern that, when mounting the electronic component 100 on the mounting board 401, as shown in FIG. 17B, the solder 402 arranged between the electronic component 100 and the mounting board 401 spreads beyond a predetermined range, causing short circuit between adjacent solders 402.

In order to suppress short circuit between the solders 402, as shown in FIG. 18A, a spacer 404 may be arranged between the frame member 102 and the mounting board 401. Alternatively, for example, as shown in FIG. 18B, a protruding portion 164, which contacts the mounting board 401, may be provided in the portion of the surface 162 of the frame member 102 arranged outside the base member 101. The protruding portion 164 functions similarly to the spacer 404. When a part of the surface 162 of the frame member 102 is made to protrude, the surface 162 side of the frame member 102 can be polished. Accordingly, improvement in the flatness and parallelism of the frame member 102 can be expected. Alternatively, for example, as shown in FIG. 18C, a protruding portion 405, that contacts the frame member 102, may be provided in the mounting board 401. The protruding portion 405 functions similarly to the spacer 404.

Alternatively, as shown in FIG. 18D, a part of the surface 152 of the base member 101 may contact the mounting board 401. The mounting board 401 is arranged so as to abut against the surface 152 of the base member 101, and the base member 101 functions as the spacer 404. Furthermore, as shown in FIG. 18E, the thickness of a region of the base member 101 in contact with the mounting board 401 may be smaller than the thickness of a region of the base member 101 not in contact with the mounting board 401. With this, for example, positioning between the electronic component 100 and the mounting board 401 can be facilitated.

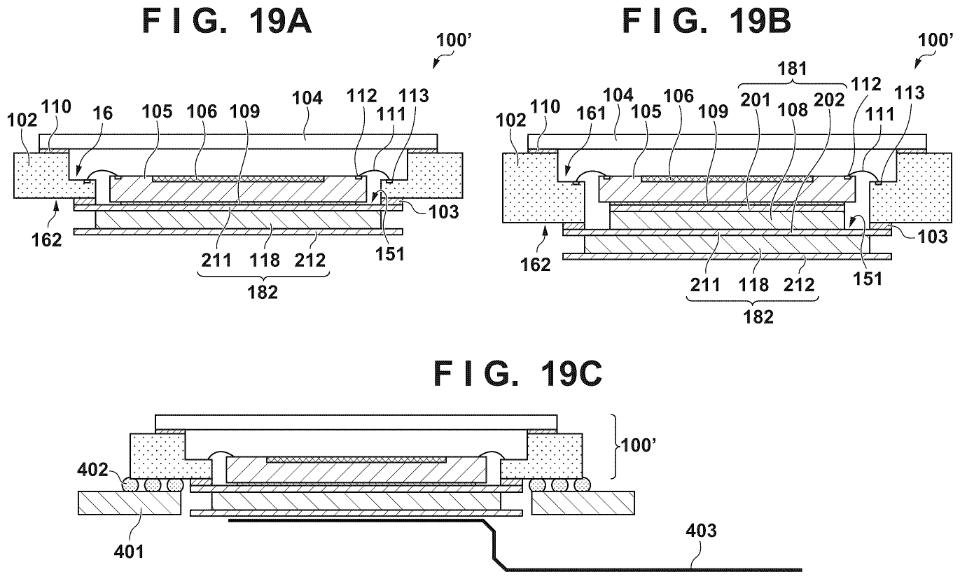

Next, with reference to FIGS. 19A to 19C, an electronic component 100′ as a modification of the electronic component 100 according to each embodiment described above will be described. In the electronic component 100 described above, the heat generating side of the Peltier element 108 included in the cooling member 181 exists as a heat source other than the semiconductor element 105. Therefore, the structure is adopted in which the heat on the heat generating side of the Peltier element 108 is hardly transmitted to the semiconductor element 105 via the base member 101, the frame member 102, and the conductive wire 111. On the other hand, in the arrangement shown in FIG. 19A, the base member 101 is not arranged. The remaining arrangement may be the same as that in each embodiment described above. The different arrangement will mainly be described below, and a description of the arrangement that may be the same will be omitted, as appropriate.

In the arrangement shown in FIG. 19A, the electronic component 100′ includes a cooling member 182, the semiconductor element 105 placed on the placement surface 151 of the cooling member 182, and the frame member 102 arranged so as to surround the side surface of the semiconductor element 105. The electrode 112 provided in the semiconductor element 105 is connected to the electrode 113 provided in the frame member 102 via the conductive wire 111. The cooling member 182 and the frame member 102 are bonded by the bonding member 103 having a lower thermal conductivity than the cooling member 182. The cooling member 182 includes a member 118 for cooling. For example, the member 118 may be a cooling fin of a heat sink or the like, or may be a heat pipe. In the arrangement shown in FIG. 19A, the cooling member 182 is shown to include base members 211 and 212, like the cooling member 181. However, depending on the shape of the member 118, the base members 211 and 212 may not be included. In the arrangement shown in FIG. 19A, the temperature can rise the most on the side of the cooling member 182 facing the semiconductor element 105. Therefore, by bonding the cooling member 182 and the frame member 102 by the bonding member 103 having a lower thermal conductivity than the cooling member 182, it is possible to suppress the heat transmitted from the cooling member 182 to the semiconductor element 105 via the frame member 102 and the conductive wire 111. As in the above description, the bonding member 103 may be a member having a lower thermal conductivity than the frame member 102.

The member 118 of the cooling member 182 may be a Peltier element, as in each embodiment described above. The base member 211 (the heat absorbing side of the Peltier element 108) and the frame member 102 are bonded via the bonding member 103. A heat conduction path between the heat generating side of the Peltier element arranged as the member 118 and the frame member 102 does not exist, a heat flow from the heat generating side of the Peltier element 108 to the semiconductor element 105 can be suppressed. In addition, since the thermal conductivity of the bonding member 103 is low, it can be suppressed that the frame member 102 and the optical member 104 are cooled more than necessary. If the frame member 102 or the optical member 104 is excessively cooled, dew condensation can occur in the optical member 104 due to the temperature difference with the surrounding environment or the like, which can affect the quality of an obtained image. As shown in FIG. 19A, by bonding the cooling member 182 and the frame member 102 using the bonding member 103 having a low thermal conductivity, such excessive cooling can be suppressed.

As shown in FIG. 19B, the cooling member 181 including the Peltier element 108 and the cooling member 182 may be stacked. The semiconductor element 105 is placed on the placement surface 151 of the cooling member 182 via the cooling member 181 including the Peltier element 108. In this case, for example, in the orthogonal projection to the placement surface 151, the outer edge of the cooling member 181 including the Peltier element 108 may be arranged inside the outer edge of the semiconductor element 105. By making the cooling member 181 fit inside the frame member 102, downsizing of the electronic component 100′ is possible. As shown in FIG. 19B, the same member may serve as the base member 202 of the cooling member 181 and the base member 211 of the cooling member 182. As described above, a Peltier element may be used as the member 118 of the cooling member 182.

As shown in FIG. 19C, the electronic component 100′ is mounted on the bonding board 401 in the same manner as the electronic component 100 described above. As described above, the mounting board 401 may be, for example, a PCB. A spacer for preventing short circuit between the solders 402 may be arranged in the same manner as described above.

It should be understood that the above-described embodiments can be used in combination, as appropriate. Such a combination is also included in the present disclosure.

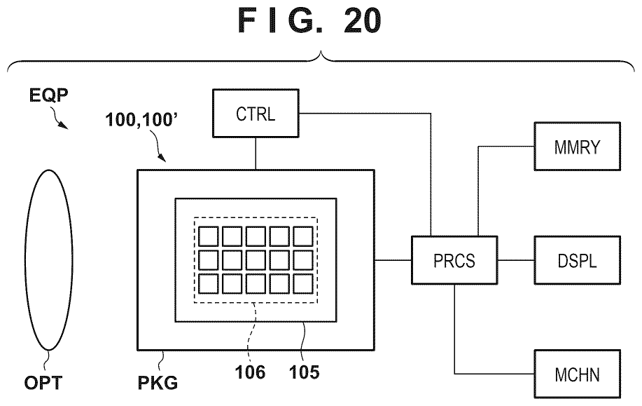

An application example of each of the electronic components 100 and 100′ according to the above-described embodiment will be described below. FIG. 20 is a schematic view showing equipment EQP mounted with the electronic component 100 or 100′. As described above, the semiconductor element 105 provided with the pixel region 106 is mounted on each of the electronic components 100 and 100′. Each of the electronic components 100 and 100′ includes a semiconductor package PKG. The semiconductor package PKG can include the base member 101 to which the semiconductor element 105 is fixed, the frame member 102, the optical member 104 such as glass facing the semiconductor element 105, a conductive bonding member such as the conductive wire 111 used to connect the electrode 113 provided in the frame member 102 or the like and the electrode 112 provided in the semiconductor element 105, and the like. The equipment EQP may further include at least one of a control device CTRL, a processing device PRCS, a display device DSPL, and a storage device MMRY.

An optical system OPT is a system for forming an image on the pixel region 106, and can be, for example, a lens, a shutter, and a mirror. The control device CTRL is a device for controlling the operation of the semiconductor element 105 mounted on the electronic component 100 or 100′, and can be, for example, a semiconductor device such as an ASIC. The processing device PRCS processes the signal output from the semiconductor element 105 mounted on the electronic component 100 or 100′, and can be, for example, a semiconductor device such as a CPU or an ASIC. The display device DSPL can be an EL display device or a liquid crystal display device that displays data obtained by the semiconductor element 105 mounted on the electronic component 100 or 100′. The storage device MMRY is a magnetic device or a semiconductor device for storing data obtained by the semiconductor element 105 mounted on the electronic component 100 or 100′. The storage device MMRY can be a volatile memory such as an SRAM or a DRAM, or a nonvolatile memory such as a flash memory or a hard disk drive. A mechanical device MCHN can include a moving or propulsion unit such as a motor or an engine. For example, the mechanical device MCHN drives the components of the optical system OPT for zooming, focusing, and shutter operations. In the equipment EQP, data output from the semiconductor element 105 mounted on the electronic component 100 or 100′ is displayed on the display device DSPL, or transmitted to an external device by a communication device (not shown) included in the equipment EQP. Hence, the equipment EQP may include the storage device MMRY and the processing device PRCS.

The equipment EQP incorporating the electronic component 100 or 100′ is also applicable as a surveillance camera or an onboard camera mounted in transportation equipment such as an automobile, a railroad car, a ship, an airplane, or an industrial robot. In addition, the equipment EQP incorporating the electronic component 100 or 100′ is not limited to transportation equipment but is also applicable to equipment that widely uses object recognition, such as an intelligent transportation system (ITS).

In this specification, expressions “A or B”, “at least one of A and B”, “at least one of A or/and B”, and “one or more of A or/and B” and the like can include all possible combinations of the listed items unless otherwise explicitly defined. That is, the above expressions are understood to disclose all of a case where at least one A is included, a case where at least one B is included, and a case where at least one A and at least one B are included. This is similarly applied to combinations of three or more elements.

The contents disclosed in this specification include a complementary set of concepts described in this specification. That is, if, for example, “A is larger than B” is described in this specification, this specification is considered to disclose “A is not larger than B” even if a description of “A is not larger than B” is omitted. This is because if “A is larger than B” is described, it is assumed that a case in which “A is not larger than B” has been considered.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2024-113632, filed Jul. 16, 2024, which is hereby incorporated by reference herein in its entirety.

What is claimed is:

1. An electronic component comprising: a base member; a Peltier element; a semiconductor element placed on a placement surface of the base member via the Peltier element; and a frame member arranged so as to surround a side surface of the semiconductor element, wherein
a first electrode provided in the semiconductor element is connected, via a conductive wire, to a second electrode provided in the frame member, and
the base member and the frame member are bonded by a bonding member having a lower thermal conductivity than the base member.

2. The component according to claim 1, further comprising an optical member arranged so as to cover the semiconductor element and bonded to the frame member.

3. The component according to claim 1, wherein the conductive wire rises from the second electrode at an angle of not more than 10° with respect to a normal to a surface of the frame member where the second electrode is arranged.

4. The component according to claim 1, wherein a thermal conductivity of the conductive wire is not more than 300 W/mK.

5. The component according to claim 1, wherein the conductive wire contains aluminum.

6. The component according to claim 1, wherein the conductive wire is arranged so as to reach a position not less than 1 mm away from the second electrode in a direction of a normal to a surface of the frame member where the second electrode is arranged.

7. The component according to claim 1, wherein the second electrode is arranged at a height between the placement surface and the semiconductor element.

8. The component according to claim 1, wherein
a first ball is formed between the conductive wire and the first electrode in a bonding portion between the conductive wire and the first electrode, and
a second ball is formed between the conductive wire and the second electrode in a bonding portion between the conductive wire and the second electrode.

9. The component according to claim 8, wherein a stitch is formed on the first ball.

10. The component according to claim 1, wherein the base member contains at least one of alumina and aluminum nitride.

11. The component according to claim 1, wherein the frame member contains at least one of alumina and aluminum nitride.

12. The component according to claim 1, wherein the base member and the frame member are formed of the same material.

13. The component according to claim 1, wherein the bonding member contains at least one of an epoxy-based resin, a silicone-based resin, and an acrylic-based resin.

14. The component according to claim 1, wherein in an orthogonal projection to the placement surface, an outer edge of the Peltier element is arranged inside an outer edge of the semiconductor element.

15. The component according to claim 1, wherein
the semiconductor element comprises a pixel region where a plurality of pixels are arranged, and
in an orthogonal projection to the placement surface, an outer edge of the Peltier element is arranged inside an outer edge of the pixel region.

16. The component according to claim 1, wherein
the semiconductor element comprises a pixel region where a plurality of pixels are arranged, and
in an orthogonal projection to the placement surface, an outer edge of the pixel region is arranged inside an outer edge of the Peltier element.

17. The component according to claim 1, wherein
a plurality of Peltier elements including the Peltier element are arranged between the placement surface and the semiconductor element, and
the plurality of Peltier elements are stacked between the placement surface and the semiconductor element.

18. The component according to claim 1, wherein
the frame member includes a first surface where the second electrode is arranged, and a second surface opposite to the first surface, and the second surface includes a portion arranged outside the base member in an orthogonal projection to the placement surface,
a third electrode is provided in the portion, and
the third electrode is connected to a fourth electrode provided in a mounting board via a solder.

19. The component according to claim 18, wherein a protruding portion, which contacts the mounting board, is provided in the portion.

20. The component according to claim 19, wherein a part of the base member is in contact with the mounting board.

21. The component according to claim 20, wherein a thickness of a region of the base member in contact with the mounting board is smaller than a thickness of a region of the base member not in contact with the mounting board.

22. The component according to claim 18, wherein in an orthogonal projection to the placement surface, the Peltier element is arranged at a position not overlapping the mounting board.

23. The component according to claim 1, wherein
the bonding member bonds a side surface of the base member and the frame member,
the Peltier element is supplied with power via a fifth electrode provided in the placement surface, and
a sixth electrode connected to the fifth electrode is provided in a surface of the base member opposite to the placement member.

24. An electronic component comprising: a cooling member; a semiconductor element placed on a placement surface of the cooling member; and a frame member arranged so as to surround a side surface of the semiconductor element, wherein
a first electrode provided in the semiconductor element is connected, via a conductive wire, to a second electrode provided in the frame member, and
the cooling member and the frame member are bonded by a bonding member having a lower thermal conductivity than the cooling member.

25. The component according to claim 24, further comprising an optical member arranged so as to cover the semiconductor element, and bonded to the frame member.

26. The component according to claim 25, wherein
a Peltier element is further arranged, and
the semiconductor element is placed on the placement surface of the cooling member via the Peltier element.

27. The component according to claim 24, wherein
the frame member includes a first surface where the second electrode is arranged, and a second surface opposite to the first surface, and the second surface includes a portion arranged outside the cooling member in an orthogonal projection to the placement surface,
a third electrode is provided in the portion, and
the third electrode is connected to a fourth electrode provided in a mounting board via a solder, and
a protruding portion, which contacts the mounting board, is provided in the portion.

28. Equipment comprising:
the electronic component according to claim 1; and
a processing device configured to process a signal output from the electronic component.

29. Equipment comprising:
the electronic component according to claim 24; and
a processing device configured to process a signal output from the electronic component.
